(19) United States
(12) Patent Application Publication
(10) Pub. No.: US 2006/0153971 A1
(43) Pub. Date: Jul. 13, 2006

(54) Display manufacturing method

(76) Inventor: Toshifumi Takehara, Kanazawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/315,011

(22) Filed: Dec. 23, 2005

(30) Foreign Application Priority Data
Jan. 13, 2005 (JP) 2005-006347

(51) Int. Cl. B05D 5/06; B05D 5/12

(52) U.S. Cl. 427/66

(57) ABSTRACT

A method of manufacturing a display includes supplying first regions on an underlayer with a first solution which contains a first organic solvent and a film-forming material dissolved or dispersed therein, wherein the first regions are spaced apart from each other, and wherein the film-forming material is to be used as a material of a layer included in a display element, selecting at least one out of the first regions which is insufficient in supply of the first solution, and supplying second regions on the underlayer surrounding the selected first region with a second solution which contains a second organic solvent and supplying the selected first region with a third solution which contains a third organic solvent and the film-forming material dissolved or dispersed therein.

### CROSS-REFERENCE TO RELATED APPLICATIONS

This application is based upon and claims the benefit of priority from prior Japanese Patent Application No. 2005-006347, filed Jan. 13, 2005, the entire contents of which are incorporated herein by reference.

### BACKGROUND OF THE INVENTION

1. Field of the Invention

The present invention relates to a display manufacturing method and, more particularly, to an organic electroluminescent (EL) display manufacturing method which forms an organic layer of an organic EL element by using an ink-jet process.

2. Description of the Related Art

Organic EL displays are self-emission display. Therefore, they have a wide viewing angle and a high response speed. Further, they do not require a backlight, and therefore, low profile and light weight are possible. For these reasons, the organic EL displays are attracting attention as displays which substitute the liquid crystal displays.

In the process of manufacturing organic EL displays, vacuum evaporation is used for forming an emission layer or buffer layer included in an organic layer in the case where a low-molecular organic material is used as a material of the emission layer or buffer layer. On the other hand, in the case where a high-molecular organic material is used as a material of an emission layer or buffer layer, it is formed by coating an underlayer with a solution which contains the high-molecular organic material and drying the coating film thus obtained.

In the latter method, for example, a partition insulting layer in which through-holes are formed correspondently with pixels is first formed on a substrate. Then, these through-holes are used as liquid reservoirs, i.e., they are filled with a solution containing the high-molecular organic material by the ink-jet process or the like. After that, the liquid films in the through-holes are dried to remove the solvent from these liquid films. In this manner, the emission layer or buffer layer is obtained.

Although this method is simple, an ink-jet nozzle is sometimes clogged with the solution containing the high-molecular organic material, i.e., an ink, so the ink is not well discharged or not discharged at all into some liquid reservoirs in some cases. If electrodes are formed on the organic layers in this state, the anodes and cathodes of organic EL elements in some pixels may shortcircuit. An organic EL element in which the anode and cathode have thus shortcircuited can no longer emit light.

Accordingly, it seems effective that the following process is carried out before forming electrodes on the organic layers. That is, a liquid reservoir into which no ink is supplied is identified, the ink is discharged into this liquid reservoir again, and the obtained coating film is dried. However, the prevent inventor has found that the brightness of a pixel having undergone this processing is significantly different from those of other pixels, and these differences are visually perceived as display unevenness, e.g., dot-like and/or line-like display unevenness.

### BRIEF SUMMARY OF THE INVENTION

According to a first aspect of the present invention, there is provided a method of manufacturing a display, comprising supplying first regions on an underlayer with a first solution which contains a first organic solvent and a film-forming material dissolved or dispersed therein, wherein the first regions are spaced apart from each other, and wherein the film-forming material is to be used as a material of a layer included in a display element, selecting at least one out of the first regions which is insufficient in supply of the first solution, and supplying second regions on the underlayer surrounding the selected first region with a second solution which contains a second organic solvent and supplying the selected first region with a third solution which contains a third organic solvent and the film-forming material dissolved or dispersed therein.

According to a second aspect of the present invention, there is provided a method of manufacturing a display, comprising supplying through-holes of a partition insulating layer formed on an insulating substrate with a first solution which contains a first organic solvent and a film-forming material dissolved or dispersed therein, wherein the film-forming material is to be used as a material of a layer included in a display element, selecting one out of the through-holes which is insufficient in supply of the first solution, and supplying regions on the partition insulating layer surrounding the selected through-hole with a second solution which contains a second organic solvent and supplying the selected through-hole with a third solution which contains a third organic solvent and the film-forming material dissolved or dispersed therein.

According to a third aspect of the present invention, there is provided a method of manufacturing a display, comprising supplying through-holes of a partition insulating layer formed on an insulating substrate with a first solution which contains a first organic solvent and a film-forming material dissolved or dispersed therein, wherein the partition insulating layer is provided with the through-holes and recesses, and wherein the film-forming material is to be used as a material of a layer included in a display element, selecting one out of the through-holes which is insufficient in supply of the first solution, and supplying parts of the recesses surrounding the selected through-hole with a second solution which contains a second organic solvent and supplying the selected through-hole with a third solution which contains a third organic solvent and the film-forming material dissolved or dispersed therein.

### BRIEF DESCRIPTION OF THE SEVERAL VIEWS OF THE DRAWING

FIG. 1 is a sectional view schematically showing an example of an organic EL display which can be manufactured by a method according to the first embodiment of the present invention;

FIG. 2 is a plan view schematically showing an example of a circuit configuration usable in the organic EL display 1 shown in FIG. 1;

FIGS. 3 to 6 are plan views schematically showing the method of manufacturing the organic EL display according to the first embodiment of the present invention;

FIG. 7 is a sectional view schematically showing an example of a display which can be manufactured by a method according to the second embodiment of the present invention;

FIGS. 8 to 11 are plan views schematically showing the method of manufacturing the organic EL display according to the second embodiment of the present invention; and

FIGS. 12 and 13 are plan views schematically showing the layout of the organic layers formed in Examples 1 and 2 of the present invention.

### DETAILED DESCRIPTION OF THE INVENTION

Several embodiments of the present invention will be described in detail below with reference to the accompanying drawing. Note that the same reference numerals in the drawing denote constituent elements which achieve the same or similar functions, and a repetitive explanation thereof will be omitted.

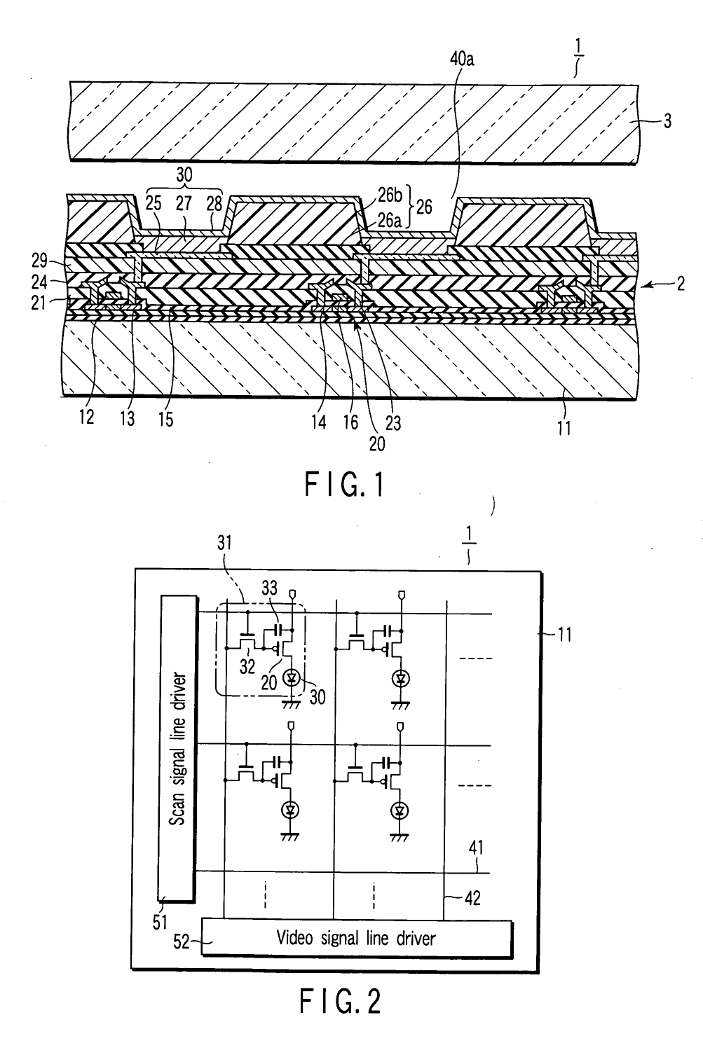

FIG. 1 is a sectional view schematically showing an example of an organic EL display which can be manufactured by a method according to the first embodiment of the present invention.

A display 1 shown in FIG. 1 is an organic EL display. The display 1 includes an array substrate 2 and sealing substrate 3 facing each other, and a sealing layer (not shown) interposed between them. This sealing layer is formed along the periphery of the sealing substrate 3, thereby forming an enclosed space between the array substrate 2 and sealing substrate 3. For example, this enclosed space is filled with a rare gas such as Ar gas or an inert gas such as N₂ gas.

The array substrate 2 has a light-transmitting insulating substrate 11 such as a glass substrate. On the substrate 11, an SiNₓ layer 12 and SiO₂ layer 13 are sequentially stacked to form an undercoat layer. On the undercoat layer, semiconductor layers 14 such as polysilicon layers in each of which a channel, source, and drain are formed, a gate insulator 15, and gate electrodes 16 are sequentially stacked to form top gate thin film transistors (TFTs) 20.

On the gate insulator 15 and gate electrodes 16, an interlayer dielectric film 21 made of SiO₂ or the like is formed. Electrode interconnections (not shown) and source and drain electrodes 23 are formed on the interlayer dielectric film 21, and buried under a passivation film 24 made of, e.g., SiNₓ. Note that the source and drain electrodes 23 are electrically connected to the source and drain, respectively, of the TFT 20 via contact holes formed in the interlayer dielectric film 21.

On the passivation film 24, a leveling layer 29 made of an organic insulator is formed. On the leveling layer 29, a plurality of anodes 25 are arranged away from each other. In this embodiment, each anode 25 is a light-transmitting conductive layer such as an indium tin oxide (ITO) layer. Each anode 25 is electrically connected to the drain electrode 23.

An insulating layer 26a is further formed on the leveling layer 29. The insulating layer 26a is, e.g., an inorganic insulating layer which is lyophilic to first and third solutions for forming an organic layer 27 (to be described later). The insulating layer 26a has through-holes at positions corresponding to the anodes 25, and covers the peripheral portions of the anodes 25 and those portions of the leveling layer 29 which are not covered with the anodes 25.

An insulating layer 26b is formed on the insulating layer 26a. The insulating layer 26b is, e.g., an organic insulating layer which is lyophobic to the first and third solutions described above. The insulating layer 26b has through-holes at positions corresponding to the anodes 25. The diameter of these through-holes is equal to or larger than that of the through-holes formed in the insulating layer 26a.

Note that the multilayered structure of the insulating layers 26a and 26b forms a partition insulating layer 26 having through-holes at positions corresponding to the anodes 25. Although the partition insulating layer 26 can have the multilayered structure of the insulating layers 26a and 26b, it may have a single-layer structure of the insulating layer 26b.

Organic layers 27 covering the anodes 25 and each including an emission layer are formed in the through-holes of the partition insulating layer 26. The emission layer is, e.g., a thin film containing a luminescent organic compound which emits red, green, or blue light. The organic layer 27 can further include one or more layers such as a buffer layer which mediates injection of holes from the anode 25 into the emission layer.

A common electrode (cathode) 28 is formed on the partition insulating layer 26 and organic layers 27. The cathode 28 is electrically connected to electrode interconnections via contact holes (not shown) formed in the passivation film 24, leveling layer 29, and partition insulating layer 29. Each organic EL element 30 includes the anode 25, organic layer 27, and cathode 28.

FIG. 2 is a plan view schematically showing an example of a circuit configuration usable in the organic EL display 1 shown in FIG. 1. As shown in FIG. 2, the organic EL display 1 includes scan signal lines 41 and video signal lines 42 arranged in a matrix form on the substrate 11, and pixels 31 are arranged in regions surrounded by the scan signal lines 41 and video signal lines 42.

The scan signal lines 41 run in the row direction and are arranged in the column direction of pixels. The scan signal lines 41 are connected to a scan signal line driver 51. The video signal lines 42 run in the column direction and are arranged in the row direction of pixels. The video signal lines 42 are connected to a video signal line driver 52.

Each pixel 31 includes a drive transistor 20 as a drive control element, the organic EL element 30, a selection transistor 32 as a selection switch, and a capacitor 33. In this embodiment, the drive transistor 20 is a p-channel TFT, and the selection transistor 32 is an n-channel TFT.

The drive transistor 20 and organic EL element 30 are connected in series between a pair of power supply terminals. The capacitor 33 is connected between the gate of the drive transistor 20 and a constant potential terminal which is a first power supply terminal in this embodiment. The selection transistor 32 is connected between the video signal line 42 and the gate of the drive transistor 20. The gate of the selection transistor 32 is connected to the scan signal line 41.

Note that the drive transistor 20, the selection transistor 32, the capacitor 33, and interconnections connecting these components form a pixel circuit. This pixel circuit controls the magnitude of an electric current flowing from the first power supply terminal to the organic EL element 30, on the basis of a scan signal supplied from the scan signal line driver 51 via the scan signal line 41, and a video signal supplied from the video signal line driver 52 via the video signal line 42.

In this embodiment, the individual layers, i.e., the emission layer, buffer layer, etc., included in the organic layer 27 of the organic EL display 1 are formed by the following method. In the following description, the method will be explained by taking a case in which the organic layer 27 includes only the emission layer as an example.

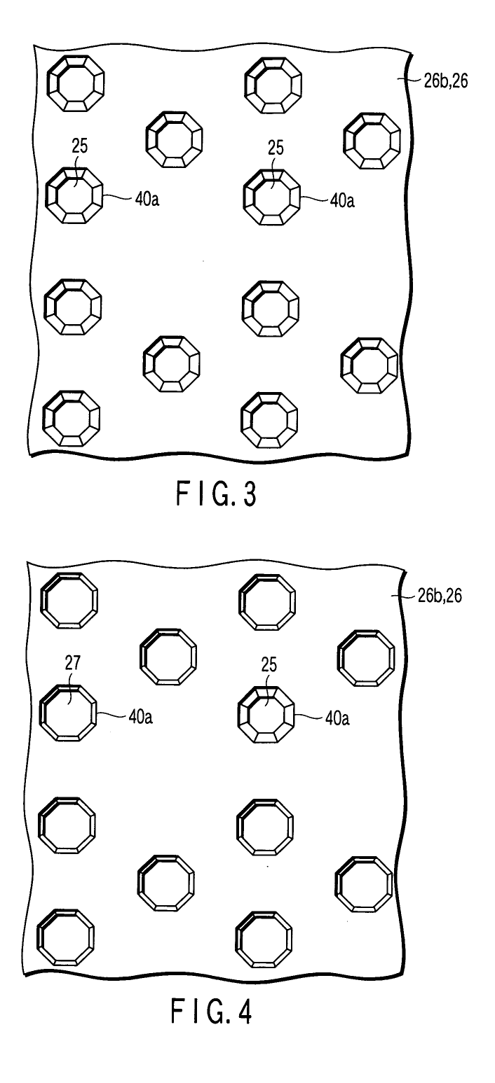

FIGS. 3 to 6 are plan views schematically showing the method of manufacturing the organic EL display according to the first embodiment of the present invention.

In this method, a structure shown in FIG. 3 is formed first. This structure shown in FIG. 3 is equivalent to the array substrate 2 shown in FIG. 1 except that the organic layer 27 and cathode 28 are omitted. In the example shown in FIG. 3, through-holes 40a each having a substantially regular octagonal shape are formed in the partition insulating layer 26. In each through-hole 40a of the partition insulating layer 26, the anode 25 is exposed.

Then, if necessary, the surface of the partition insulating layer 26 is made lyophobic by using a plasma gas such as CF₄/O₂. In this manner, the surface of the insulating layer 26b is made lyophobic to a first solution which is prepared by dissolving or dispersing the material of an organic layer 27 in an organic solvent.

As shown in FIG. 4, an organic layer 27 containing the organic solvent is formed by supplying a predetermined amount of the first solution into each through-hole 40a by the ink-jet process. When three types of blue, green, and red emission organic layers are to be formed as the organic layers 27, three types of first solutions corresponding to these organic layers are prepared, and discharged into the through-holes 40a of blue, green, and red display pixels 31, respectively. In this embodiment, the three types of first solutions are discharged in parallel by using an ink-jet apparatus having an ink-jet head including at least one first solution ink-jet nozzle for each display color. Note that the ink-jet head of the ink-jet apparatus herein used further includes at least one ink-jet nozzle for a second solution (to be described later).

After the operation of discharging the first solutions into all the through-holes 40a is completed, whether there is a through-hole 40a in which the supply amount of the first solution is insufficient is checked by using, e.g., an image processing technique. If there is no through-hole 40a in which the first solution supply amount is insufficient, a drying process is performed to almost completely remove the organic solvent from the organic layers 27. After that, the array substrate 2 is completed by forming a cathode 28.

On the other hand, if there is a through-hole 40a in which the first solution supply amount is insufficient, positional information of this through-hole is recorded. Preferably, the degree of deficiency of the first solution supply amount of the through-hole 40a is also recorded together with the positional information. The degree of deficiency of the first solution supply amount can be measured from, e.g., the presence/absence of the organic layer 27 or the planar shape, area, or the like of the organic layer 27. After that, the following step is performed.

That is, on the basis of the positional information described above, as shown in FIG. 5, a second solution containing an organic solvent is supplied around the through-hole 40a in which the first solution supply amount is insufficient, on the upper surface of the partition insulating layer 26, by the ink-jet process. In this way, the through-hole 40a is surrounded by a plurality of liquid films 45. The supply amount of the second solution to the upper surface of the partition insulating layer 26 is so set that the adjacent liquid films 45 do not connect to each other and the second solution does not flow into the through-hole 40a.

In addition to that, a third solution is supplied by the ink-jet process into the through-hole 40a in which the first solution supply amount is insufficient, thereby forming an organic layer 27 containing an organic solvent. The third solution is prepared by dissolving or dispersing the material of the organic layer 27 in the organic solvent. The supply amount of the third solution is constant or substantially corresponds to the deficiency of the first solution supply amount.

Note that the second and third solutions are so supplied that a period during which the organic solvent volatilizes from the liquid films 45 and a period during which the organic solvent volatilizes from the organic layer 27 formed by using the third solution at least partially overlap each other. Typically, the second and third solutions are supplied substantially simultaneously. For example, immediately after the second solution is supplied around a certain through-hole 40a, the third solution is supplied into the through-hole 40a.

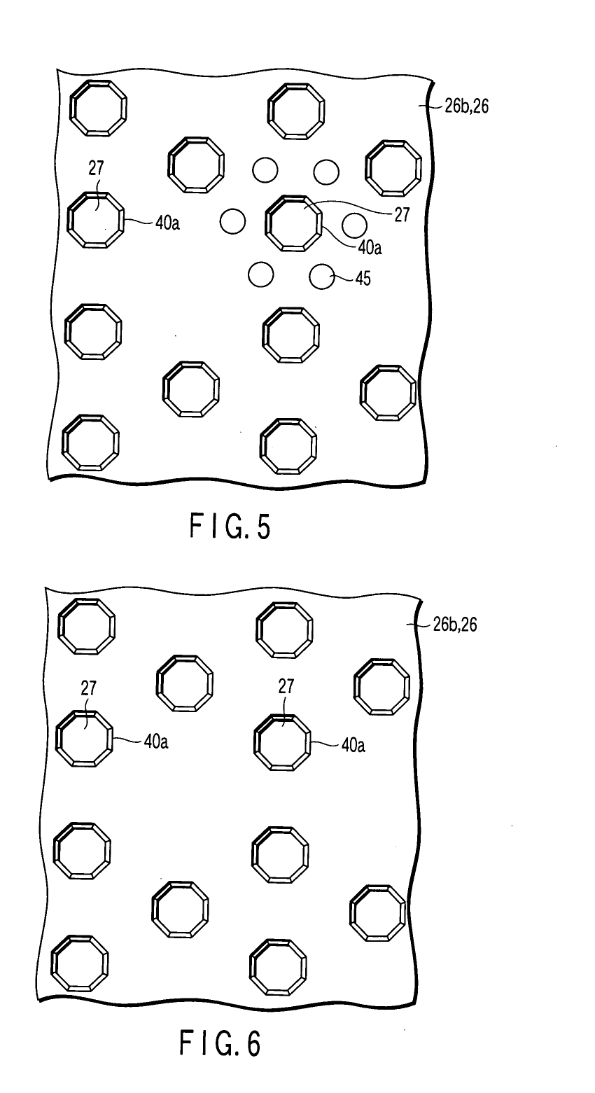

After that, the organic solvent contained in the organic layers 27 and liquid films 45 is vaporized. In this way, a structure shown in FIG. 6 is obtained.

Each organic layer 27 formed in the step explained with reference to FIG. 4 is surrounded by a plurality of organic layers 27. Also, each organic layer 27 and organic layers 27 around it dry at substantially the same time. Therefore, the drying of the organic layers 27 progresses in an ambient containing the organic solvent at a high concentration.

As shown in FIG. 5, when the organic layer 27 formed by supplying the third solution into the through-hole 40a in which the first solution supply amount is insufficient dries, if the through-hole 40a is surrounded by the liquid films 45 made of the second solution, the organic solvent vaporizes not only from the organic layer 27 formed in the through-hole 40a but also from the liquid films 45. Therefore, in this case, a concentration of the organic solvent in an ambient near the through-hole 40a, in which the first solution supply amount is insufficient, is higher than the case where no liquid films 45 are formed. That is, when the liquid films 45 are formed, the drying of the organic layer 27 progresses under conditions close to the drying conditions of the organic layers 27 formed in the step shown in FIG. 4, more specifically, under moderate conditions, when compared to the case in which no liquid films 45 are formed. This reduces, e.g., the variation in film thickness profile or the like of the organic layer 27 between the pixel 31 in which the organic layer 27 is formed in the step shown in FIG. 4 and the pixel 31 in which the organic layer 27 is formed in the step shown in FIG. 5. This makes it possible to suppress the occurrence of display unevenness.

Note that even when formation of the organic layer 27 in the through-hole 40a in which the first solution supply amount is insufficient is performed in a processing vessel filled with a gas containing an organic solvent at a high concentration instead of forming the liquid films 45, it is possible to create conditions substantially equal to the drying conditions of the organic layers 27 formed in the step shown in FIG. 4. In this case, however, even the organic layers 27 formed in the step shown in FIG. 4 are exposed to the ambient containing the organic solvent at a high concentration. Thus exposing the organic layers 27 to the ambient containing the organic solvent at a high concentration again has a large influence on the emission characteristics of the obtained organic EL elements 30. This makes it difficult to make the brightness of the organic EL element 30 having the organic layer 27 formed in the step shown in FIG. 4 equal to that of the organic EL element 30 having the organic layer 27 formed in the step shown in FIG. 5, or to make the brightness of the organic EL display 1 manufactured by performing the step shown in FIG. 5 equal to that of the organic EL display 1 manufactured without the step shown in FIG. 5.

By contrast, as explained with reference to FIG. 5, the method using the liquid films 45 can locally produce the ambient containing the organic solvent at a high concentration. Accordingly, conditions substantially equal to the drying conditions of the organic layers 27 formed in the step shown in FIG. 4 can be created without exposing most organic layers 27 already having dried to some extent to the ambient containing the organic solvent at a high concentration again. According to this embodiment, therefore, it is easy to make the brightness of the organic EL element 30 having the organic layer 27 formed in the step shown in FIG. 4 equal to that of the organic EL element 30 having the organic layer 27 formed in the step shown in FIG. 5, or to make the brightness of the organic EL display 1 manufactured by performing the step shown in FIG. 5 equal to that of the organic EL display 1 manufactured without the step shown in FIG. 5.

The second embodiment of the present invention will now be described below.

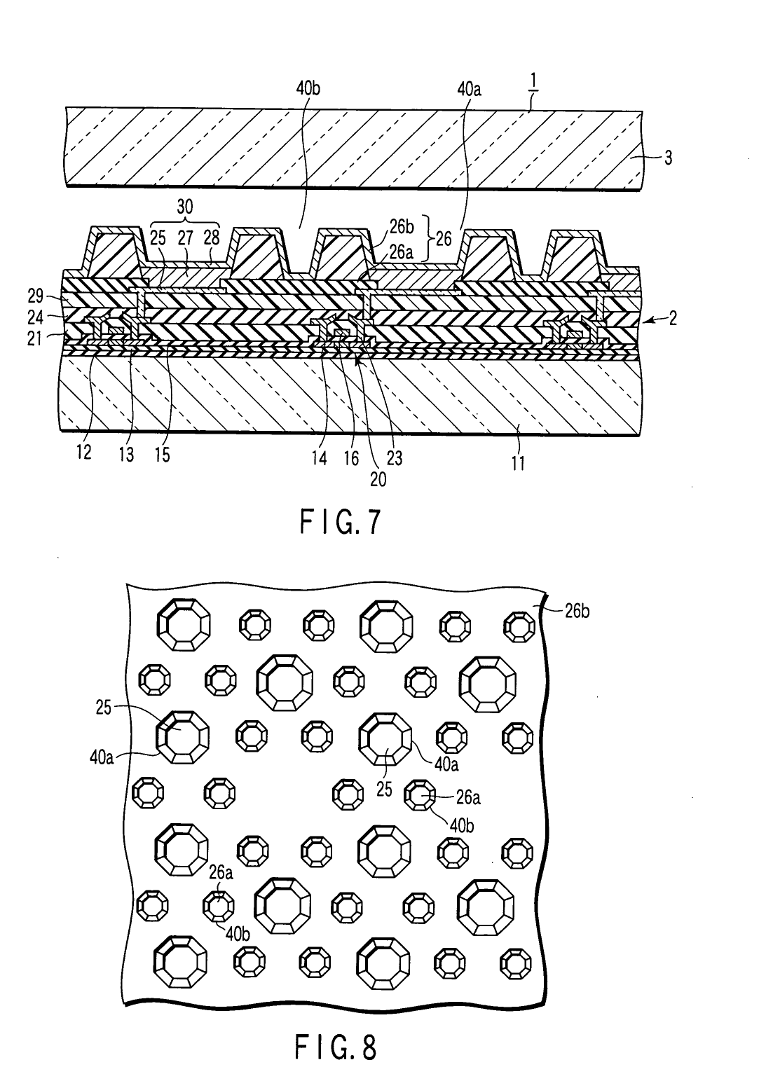

FIG. 7 is a sectional view schematically showing an example of a display which can be manufactured by a method according to the second embodiment of the present invention. A display 1 shown in FIG. 7 is an organic EL display. The display 1 has the same structure as the organic EL display 1 shown in FIG. 1 except that a plurality of recesses 40b are formed on the upper surface of a partition insulating layer 26 so as to surround each through-hole 40a. In this embodiment, as an example, the upper surface of an insulating layer 26a is used as the bottom surface of each recess 40b by forming a through-hole in an insulating layer 26b. However, the recesses 40b may be formed by forming through-holes in both the insulating layers 26a and 26b.

In this embodiment, individual layers, i.e., an emission layer, buffer layer, etc., included in an organic layer 27 of the organic EL display 1 are formed by the following method. In the following description, the method will be explained by taking a case in which the organic layer 27 includes only the emission layer as an example.

FIGS. 8 to 11 are plan views schematically showing the method of manufacturing the organic EL display according to the second embodiment of the present invention.

In this method, a structure shown in FIG. 8 is formed first. The structure shown in FIG. 8 is equivalent to the array substrate 2 shown in FIG. 7 except that the organic layers 27 and a cathode 28 are omitted. In the example shown in FIG. 8, the through-holes 40a each having a substantially regular octagonal shape are formed in the insulating layers 26a and 26b of the partition insulating layer 26. In each through-hole 40a of the partition insulating layer 26, an anode 25 is exposed. Also, in the example shown in FIG. 8, substantially regular octagonal through-holes having a diameter smaller than that of the through-holes 40a are further formed only in the insulating layer 26b of the partition insulating layer 26. These through-holes and the upper surface of the insulating layer 26a form the recesses 40b having substantially regular octagonal openings.

Then, if necessary, as in the first embodiment, the surface of the partition insulating layer 26 is made lyophobic by using a plasma gas such as CF₄/O₂. In this manner, the surface of the insulating layer 26b is made lyophobic to a first solution which is prepared by dissolving or dispersing the material of an organic layer 27 in an organic solvent.

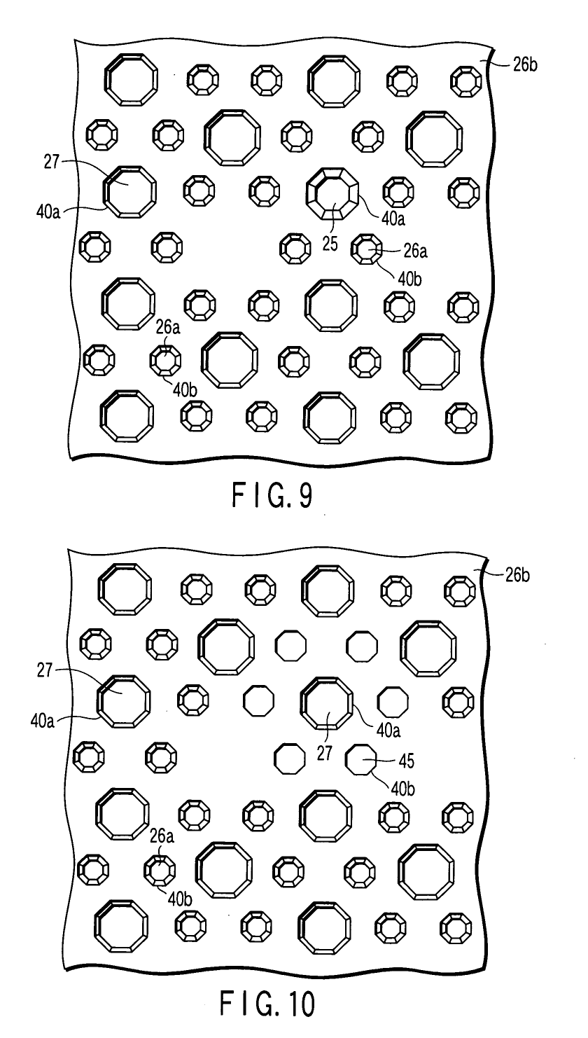

As shown in FIG. 9, as in the first embodiment, an organic layer 27 containing the organic solvent is formed by supplying a predetermined amount of the first solution into each through-hole 40a by the ink-jet process. In this case, attention should be paid so as not to supply the first solution into the recesses 40b.

After the operation of discharging the first solution into all the through-holes 40a is completed, whether there is a through-hole 40a in which the supply amount of the first solution is insufficient is checked by using, e.g., an image processing technique. If there is no through-hole 40a in which the first solution supply amount is insufficient, a heating process is performed to almost completely remove the organic solvent from the organic layers 27. After that, the array substrate 2 is completed by forming a cathode 28.

On the other hand, if there is a through-hole 40a in which the first solution supply amount is insufficient, positional information of this through-hole is recorded. Preferably, the degree of deficiency of the first solution supply amount of the through-hole 40a is also recorded together with the positional information. After that, the following step is performed.

That is, on the basis of the positional information described above, as shown in FIG. 10, a second solution containing an organic solvent is supplied by the ink-jet process into the recesses 40b surrounding the through-hole 40a in which the first solution supply amount is insufficient. The amount of second solution supplied to the recesses 40b is so set that the second solution does not overflow from each recess 40b.

In addition to that, a third solution is supplied by the ink-jet process into the through-hole 40a in which the first solution supply amount is insufficient, thereby forming an organic layer 27 containing an organic solvent. The supply amount of the third solution is constant or substantially corresponds to the deficiency of the first solution supply amount.

Note that the second and third solutions are so supplied that a period during which the organic solvent volatilizes from liquid films 45 and a period during which the organic solvent volatilizes from the organic layer 27 formed by using the third solution at least partially overlap each other. Typically, the second and third solutions are supplied substantially simultaneously. For example, immediately after the second solution is supplied around a certain through-hole 40a, the third solution is supplied into the through-hole 40a.

After that, the organic solvent contained in the organic layers 27 and liquid films 45 are vaporized. In this way, a structure shown in FIG. 11 is obtained.

This method is substantially the same as the method explained in the first embodiment. Therefore, substantially the same effects as explained in the first embodiment can be obtained by this embodiment.

Also, in this embodiment, the recesses 40b are formed on the upper surface of the partition insulating layer 26, and the second solution is supplied into the recesses 40b. When compared to the first embodiment, therefore, the second solution does not easily flow into the through-holes 40a. In addition, if the insulating layer 26b is equally lyophobic to the first and second solutions, the supply of the second solution requires no such high positional accuracy as in the first embodiment.

The amount of second solution used in the formation of the liquid films 45 is not particularly limited, provided that the organic layers 27 formed by using the third solution can be dried under substantially the same conditions as the drying conditions of the organic layers 27 formed by using the first solution. For example, the amount of organic solvent contained in the third solution supplied into one through-hole 40a can be substantially equal to that of organic solvent contained in the liquid films 45 surrounding the through-hole 40a.

The compositions of the first and third solutions used in the methods explained in the first and second embodiments can be the same or different. However, the organic material contained as a solute or dispersoid in the first solution is the same as the organic material contained as a solute or dispersoid in the third solution. Also, the organic solvents contained in the first and third solutions are typically the same.

The organic solvents contained in the second and third solutions can be the same or different. Typically, the organic solvents contained in the second and third solutions are the same.

Examples of the organic solvent contained in the first to third solutions include tetralin, toluene, cyclohexane, anisole, and diphenyl ether.

The second solution can further contain a component other than the organic solvent. In the ink-jet process, highly accurate discharging is sometimes difficult to perform if the viscosity of a solution to be discharged is too low or too high. Also, if the viscosity of the discharged solution is too low, the discharged solution may undesirably move on the surface on which the solution is discharged. When a solute or dispersoid is added to the second solution in addition to the organic solvent, the viscosity of the second solution can be adjusted in accordance with the type, content, or the like of the solute or dispersoid.

The solute or dispersoid which can be contained in the second solution can be any of an inorganic material, an organic material, and their mixture. Also, this solute or dispersoid can be any of an insulator, semiconductor, and conductor. Normally, an insulator is used as the solute or dispersoid.

Examples of the inorganic material which can be contained as a solute or dispersoid in the second solution include aluminum oxide, silicon oxide, and silicon nitride.

Examples of the organic material which can be contained as a solute or dispersoid in the second solution include tetralin, toluene, cyclohexane, anisole, and diphenyl ether. As this organic material, the same organic material as that contained as a solute or dispersoid in the first and third solutions may be used. In this case, if the first to third solutions have the same composition, the same ink-jet nozzle can be used to discharge the first to third solutions. Accordingly, the structure of the ink-jet apparatus can be simplified.

Note that when a solute or dispersoid is further added to the second solution in addition to the organic solvent, a characteristic structure explained below appears in the organic EL display 1.

For example, when the second solution containing the organic solvent and the solute or dispersoid is used in the method explained with reference to FIGS. 3 to 6, the material contained as the solute or dispersoid in the second solution remains in the form of a thin film at the positions of the liquid films 45 shown in FIG. 5 when the step shown in FIG. 6 is completed.

Also, when the second solution containing the organic solvent and the solute or dispersoid is used in the method explained with reference to FIGS. 8 to 11, the material contained as the solute or dispersoid in the second solution remains in the form of a thin film at the positions of the liquid films 45 shown in FIG. 10 when the step shown in FIG. 11 is completed.

Accordingly, whether the completed organic EL display is manufactured through one of the process shown in FIGS. 3 to 6 and the process shown in FIGS. 8 to 11 can be determined by checking the presence/absence of the material remaining in the form of a thin film. In addition, whether the organic EL display is manufactured through the process shown in FIGS. 3 to 6 or the process shown in FIGS. 8 to 11 can be determined by checking the presence/absence of the recesses 40b.

Materials usable for the constituent elements of the organic EL display 1 will be explained below.

As the insulating substrate 11, any substrate can be used as long as it can support a structure to be formed on it. A hard substrate such as a glass substrate is generally used as the substrate 11. However, a flexible substrate such as a plastic sheet may also be used.

When the organic EL display 1 is a bottom emission display which emits light from the side of the substrate 11, a light-transmitting transparent electrode is used as the anode 25. As the material of this transparent electrode, a transparent conductive material such as ITO can be used. The film thickness of the transparent electrode is normally about 10 to 150 nm. The transparent electrode can be obtained by depositing a transparent conductive material such as ITO by, e.g., evaporation or sputtering, and patterning the obtained thin film by using photolithography.

As the material of the insulating layer 26a, an inorganic insulating material such as silicon nitride or silicon oxide can be used. The insulating layer 26a made of any of these inorganic insulating materials have relatively high lyophilicity.

An organic insulating material or the like can be used as the material of the insulating layer 26b. An organic insulating material usable as the insulating layer 26b is not particularly limited. When a photosensitive resin is used, however, formation of the insulating layer 26b having through-holes is easy. An example of the photosensitive resin usable in the formation of the insulating layer 26b is a material which is obtained by adding a photosensitive compound such as naphthoquinonediazide to an alkali-soluble polymer derivative such as phenolic resin, polyacryl, polyamide resin, or polyamic acid, and which gives a positive pattern upon exposure and alkali development. An example of a photosensitive resin which gives a negative pattern is a photosensitive composition which decreases the rate of dissolution to a developer when irradiated with actinic radiation, e.g., a photosensitive composition having a functional group such as an epoxy group which crosslinks when irradiated with actinic radiation. For example, the insulating layer 26b can be obtained by coating the surface of the substrate 11 on which the anodes 25 and the like are formed with any of these photosensitive resins by spin coating or the like, and patterning the obtained coating film by using photolithography.

The film thickness of the partition insulating layer 26 is desirably equal to or larger than that of the organic layer 27, and normally about 0.09 to 0.13 μm. Also, the film thickness of the insulating layer 26a is normally about 0.05 to 0.1 μm.

The organic layer 27 includes an emission layer. As the material of this emission layer, a luminescent organic compound generally used in organic EL displays can be used. Examples of an organic compound which emits red luminescence include a polymer compound having an alkyl or alkoxy substituent in a benzene ring of a polyvinylenestyrene derivative, and a polymer compound having a cyano group in a vinylene group of a polyvinylenestyrene derivative. An example of an organic compound which emits green luminescence is a polyvinylenestyrene derivative in which an alkyl, alkoxy, or aryl derivative substituent is introduced into a benzene ring. An example of an organic compound which emits blue luminescence is a polyfluorene derivative such as a copolymer of dialkylfluorene and anthracene. It is also possible to further add a low-molecular luminescent organic compound to the emission layer in addition to any of the high-molecular luminescent organic compounds described above.

The film thickness of the emission layer is appropriately set in accordance with the material to be used. Normally, the film thickness of the whole emission layer is 50 to 200 nm.

As described above, the organic layer 27 can further include a buffer layer and the like in addition to the emission layer. As the material of this buffer layer, it is possible to use, e.g., a mixture of a donor polymer organic compound and acceptor polymer organic compound. As the donor polymer organic compound, it is possible to use, e.g., a polythiophene derivative such as polyethylenedioxythiophene (PEDOT) and/or a polyaniline derivative such as polyaniline. As the acceptor polymer organic compound, polystyrenesulfonic acid (PSS) or the like can be used.

At least one layer included in the organic layer 27 is formed by the method explained with reference to FIGS. 3 to 6 or the method explained with reference to FIGS. 8 to 11. For example, when the organic layer 27 includes an emission layer and another layer such as a buffer layer, at least the emission layer is typically formed by the method explained with reference to FIGS. 3 to 6 or the method explained with reference to FIGS. 8 to 11. Note that the organic solvent can be removed from each layer included in the organic layer 27 under heating and/or reduced pressure, or by natural seasoning.

The cathode 28 can have a single-layer structure or multilayered structure. When the cathode 28 has a multilayered structure, this multilayered structure can be a two-layered structure obtained by sequentially stacking a main conductive layer containing barium or calcium and a protective conductor layer containing silver or aluminum on the organic layer 27. Alternatively, the multilayered structure can be a two-layered structure obtained by sequentially stacking a non-conductor layer containing barium fluoride or the like and a conductor layer containing silver or aluminum on the organic layer 27. It is also possible to use a three-layered structure obtained by sequentially stacking a non-conductor layer containing barium fluoride or the like, a main conductor layer containing barium or calcium, and a protective conductor layer containing silver or aluminum on the organic layer 27.

In each of the first and second embodiments, the method of forming the organic layer 27 is explained by taking a specific structure as an example. However, the methods explained in the first and second embodiments are usable in the manufacture of various organic EL displays. For example, the structure having the leveling layer 29 is shown in FIGS. 1 and 7, but the leveling layer 29 may be omitted. Also, the anode 25 is formed on the leveling layer 29 in the structure shown in FIGS. 1 and 7, but the anode 25 may be formed on the interlayer dielectric film 21. That is, the video signal lines and the anodes 25 may be formed on the same underlayer.

Although the organic EL display 1 shown in FIGS. 1 and 7 is a bottom emission display, the above-mentioned method can also be used in the manufacture of a top emission organic EL display. Furthermore, when the array substrate 2 is to be sealed by the counter substrate 3, the life of elements can be prolonged by encapsulating a desiccant in the space between the substrates. It is also possible to improve the heat radiation characteristics by filling a resin between the counter substrate 3 and array substrate 2.

When the first solution is supplied to a row of the liquid reservoirs by the ink-jet process, the nozzle for the second solution may be used to supply the second solution to adjacent row of the liquid reservoirs or vicinity thereof. In this case, the second solution desirably contains the same organic solvent as that contained in the first solution. In this manner, it is possible to suppress display unevenness caused by the film thickness distribution unevenness of the organic layer resulting from the difference between the drying rates of the organic solvents. The second solution can be supplied to either the inside or periphery of the through-hole 41a.

The ink-jet apparatus has one ink-jet head having a plurality of ink-jet nozzles. However, the apparatus may have separate heads for the individual display colors, or the ink-jet nozzle for the second solution may be mounted on an ink-jet head different from the ink-jet head mounting the ink-jet nozzle for the first solution. In this case, each ink-jet head may have a plurality of ink-jet nozzles.

Examples of the present invention will be described below.

### EXAMPLE 1

In this example, the organic EL display 1 shown in FIG. 1 was manufactured by the following method.

First, film formation and pattering were repetitively performed in the same manner as the normal TFT formation process on the surface of a glass substrate 11 on which undercoat layers 12 and 13 were formed, thereby forming TFTs 20, an interlayer dielectric film 21, electrode interconnections (not shown), source and drain electrodes 23, a passivation film 24, and a leveling layer 29.

Then, an ITO film was formed on the leveling layer 29 by using sputtering. Subsequently, this ITO film was patterned by using photolithography to obtain anodes 25. Note that the anodes 25 may also be formed by mask sputtering.

On the surface of the substrate 11 on which the anodes 25 were formed, an insulating layer 26a having openings at positions corresponding to emission portions of pixels was formed. Subsequently, the insulating layer 26a and the anodes 25 were coated with a photosensitive resin, and pattern exposure and development were performed on the obtained coating film, thereby forming an insulating layer 26b having openings at positions corresponding to the emission portions of the pixels. In this manner, a layered structure including the insulating layer 26a made of a silicon nitride film and the insulating layer 26b made of polyimide was obtained as a partition insulating layer 26. Note that the surface of the insulating layer 26b was fluorinated by performing a surface treatment using CF₄/O₂ plasma gas on the partition insulating layer 26.

Then, blue, green, and red emission layers were formed in liquid reservoirs formed by the partition insulating layer 26, by using the method explained with reference to FIGS. 3 to 6.

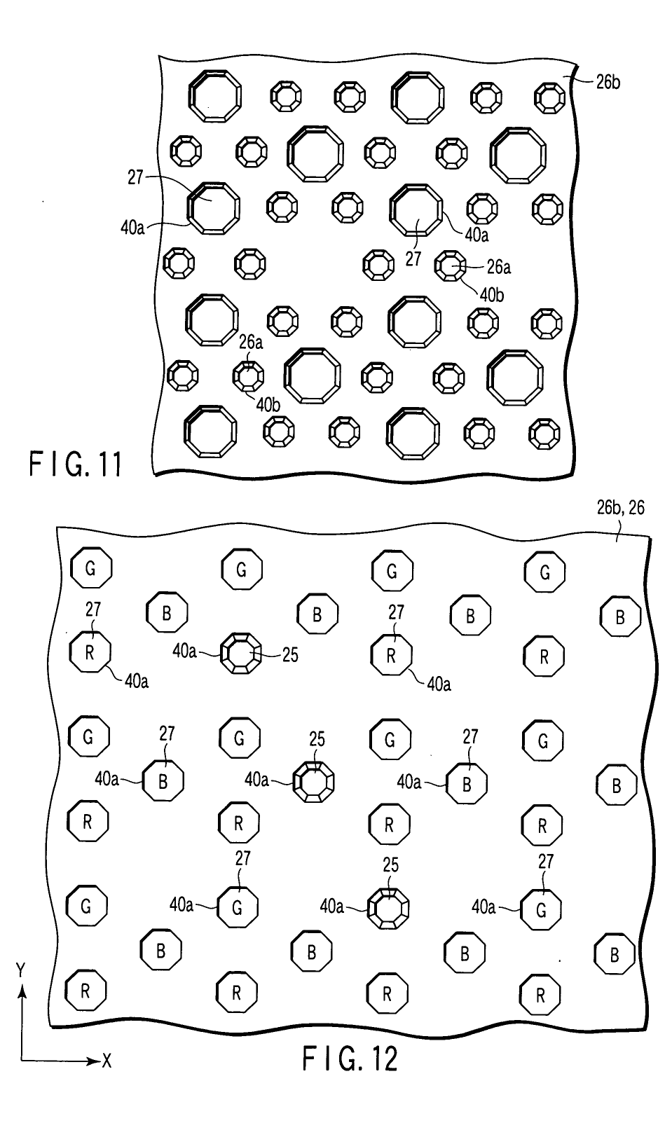

More specifically, blue, green, and red luminescent organic compounds were dissolved in an organic solvent (toluene) to prepare three types of solutions as first solutions. Then, as shown in FIG. 12, the first solutions were discharged by the ink-jet process into some of through-holes 40a formed in the partition insulating layer 26, thereby forming organic layers 27. In this example, the organic layers 27 corresponding to the individual emission colors were formed by discharging the first solutions from a plurality of ink-jet nozzles arranged in the Y direction at the timing when ink droplets were supplied into the through-holes 40a, while a nozzle head and the insulating substrate 11 were moved relative to each other in the X direction. Note that in FIG. 12, reference symbols B, G, and R attached to the organic layers 27 indicate that these organic layers were formed by using the first solutions containing the blue, green, and red luminescent organic compounds, respectively.

Then, a second solution was supplied by the ink-jet process to regions surrounding each through-hole 40a to which the first solutions were not supplied, thereby forming a plurality of liquid films 45 arranged as shown in FIG. 5. In this example, the same organic solvent as used in the first solutions was used as the second solution. Also, the amount of first solution supplied into one through-hole 40a was substantially equal to the sum of the amounts of second solution supplied around one through-hole 40a.

At substantially the same time the second solution was supplied, third solutions were discharged by the ink-jet process only into through-holes 40a to which the first solutions were not supplied. In this example, the third solutions had the same compositions as that of the first solutions. Also, the amount of third solution supplied into one through-hole 40a was substantially equal to that of first solution supplied into one through-hole 40a.

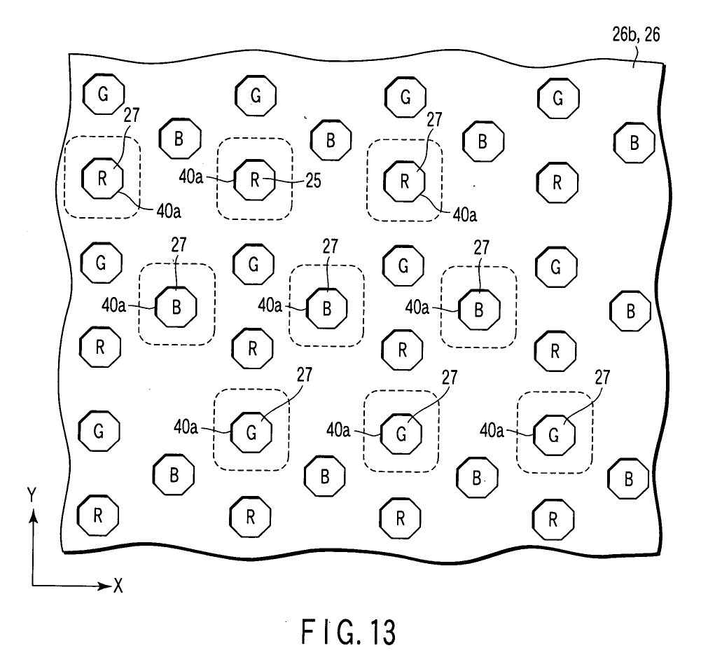

After the organic solvent substantially completely vaporized from the liquid films 45, the coating films formed by using the first and third solutions were heated at a temperature of 90° C. for 1 hr, thereby obtaining emission layers. In this way, as shown in FIG. 13, blue, green, and red emission layers were obtained as the organic layers 27. Note that in FIG. 13, organic layers 27 surrounded by the dotted lines were formed by using the third solutions, and other organic layers 27 were formed by using the first solutions.

After the organic layers 27 were thus formed, barium was evaporated in a vacuum onto the organic layers 27, and aluminum was subsequently evaporated, thereby forming a cathode 28. In this manner, an array substrate 2 was completed.

After that, the peripheral portion of one main surface of a glass substrate 3 was coated with an ultraviolet-curing resin to form a sealing layer. The glass substrate 3 and array substrate 2 were then put together in an inert gas such that the surface of the glass substrate 3 on which the sealing layer was formed faced the surface of the array substrate 2 on which the cathode 28 was formed. Furthermore, the sealing layer was cured by ultraviolet radiation, thereby completing the organic EL display 1 shown in FIG. 1.

Then, brightness of a pixel 31 having the organic layer 27 formed by using the first solution and that of a pixel 31 having the organic layer 27 formed by using the third solution were measured for each color.

More specifically, of the organic layers 27 shown in FIG. 13, a pair of pixels 31 having the organic layers 27 surrounded by the broken lines (formed by using the first solution) and a pixel 31 having the organic layer 27 surrounded by the dotted line (formed by using the third solution) were selected for each emission color, and the brightness values of these pixels were measured. In this example, the current density of an electric current to be supplied to the organic layer 27 was set at 20.0 mA/cm² for blue and green emission pixels 31, and at 45.2 mA/cm² for a red emission pixel 31.

After that, the brightness values of the pair of pixels 31 were averaged, and the relative brightness of the pixel 31 having the organic layer 27 formed by using the third solution with respect to the pixel 31 having the organic layer 27 formed by using the first solution was calculated. The results are summarized in a table below.

### EXAMPLE 2

The organic EL display 1 shown in FIG. 1 was manufactured by the same method as explained in Example 1 except that second solutions having the same compositions as first solutions were used. Then, the relative brightness of a pixel 31 having an organic layer 27 formed by using a third solution with respect to a pixel 31 having an organic layer 27 formed by using the first solution was obtained by the same method as that explained in Example 1. The results are summarized in the table below.

### COMPARATIVE EXAMPLE

The organic EL display 1 shown in FIG. 1 was manufactured by the same method as explained in Example 1 except that no second solution was used. Then, the relative brightness of a pixel 31 having an organic layer 27 formed by using a third solution with respect to a pixel 31 having an organic layer 27 formed by using a first solution was obtained by the same method as that explained in Example 1. The results are summarized in the table below.

| | Relative brightness (%) | | |
|---|---|---|---|
| | Blue | Green | Red |
| Example 1 | 95 | 96 | 97 |
| Example 2 | 96 | 97 | 98 |
| Comparative | 120 | 120 | 120 |
| example | | | |

As shown in the above table, in the organic EL display 1 according to the comparative example, the brightness of the pixel 31 having the organic layer 27 formed by using the third solution was much higher than that of the pixel 31 having the organic layer 27 formed by using the first solution. When an image was displayed on the organic EL display 1 according to the comparative example and the displayed image was observed, the pixel 31 having the organic layer 27 formed by using the third solution was visually perceived as a dot defect.

On the other hand, in the organic EL displays according to Examples 1 and 2, as shown in the above table, the brightness of the pixel 31 having the organic layer 27 formed by using the third solution was substantially equal to that of the pixel 31 having the organic layer 27 formed by using the first solution. When images were displayed on the organic EL displays 1 according to Examples 1 and 2 and the displayed images were observed, it was impossible to discriminate between the pixel 31 having the organic layer 27 formed by using the third solution and the pixel 31 having the organic layer 27 formed by using the first solution.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a display, comprising:
supplying first regions on an underlayer with a first solution which contains a first organic solvent and a film-forming material dissolved or dispersed therein, wherein the first regions are spaced apart from each other, and wherein the film-forming material is to be used as a material of a layer included in a display element;
selecting at least one out of the first regions which is insufficient in supply of the first solution; and
supplying second regions on the underlayer surrounding the selected first region with a second solution which contains a second organic solvent and supplying the selected first region with a third solution which contains a third organic solvent and the film-forming material dissolved or dispersed therein.

2. The method according to claim 1, wherein the layer included in the display element is an organic layer included in an organic EL element, and wherein the film-forming material is an organic material.

3. The method according to claim 2, wherein the organic layer is an emission layer.

4. The method according to claim 2, wherein supplying the first regions with the first solution, supplying the second regions with the second solution, and supplying the selected first region with the third solution are carried out by ink-jet process.

5. The method according to claim 1, wherein supplying the first regions with the first solution, supplying the second regions with the second solution, and supplying the selected first region with the third solution are carried out by ink-jet process.

6. The method according to claim 1, wherein supplying the second regions with the second solution is carried out before supplying the selected first region with the third solution.

7. The method according to claim 1, wherein the second solution consists of the second organic solvent and unavoidable impurities.

8. The method according to claim 1, wherein the second solution further contains the film-forming material.

9. The method according to claim 1, the first and third solutions are equal in composition to each other.

10. A method of manufacturing a display, comprising:
supplying through-holes of a partition insulating layer formed on an insulating substrate with a first solution which contains a first organic solvent and a film-forming material dissolved or dispersed therein, wherein the film-forming material is to be used as a material of a layer included in a display element;
selecting one out of the through-holes which is insufficient in supply of the first solution; and
supplying regions on the partition insulating layer surrounding the selected through-hole with a second solution which contains a second organic solvent and supplying the selected through-hole with a third solution which contains a third organic solvent and the film-forming material dissolved or dispersed therein.

11. The method according to claim 10, wherein the layer included in the display element is an organic layer included in an organic EL element, and wherein the film-forming material is an organic material.

12. The method according to claim 11, wherein the organic layer is an emission layer.

13. The method according to claim 11, wherein supplying the through-holes with the first solution, supplying the regions with the second solution, and supplying the selected through-hole with the third solution are carried out by ink-jet process.

14. The method according to claim 10, wherein supplying the through-holes with the first solution, supplying the regions with the second solution, and supplying the selected through-hole with the third solution are carried out by ink-jet process.

15. The method according to claim 10, wherein supplying the regions with the second solution is carried out before supplying the selected through-hole with the third solution.

16. The method according to claim 10, wherein the second solution consists of the second organic solvent and unavoidable impurities.

17. The method according to claim 10, wherein the second solution further contains the film-forming material.

18. The method according to claim 10, the first and third solutions are equal in composition to each other.

19. A method of manufacturing a display, comprising:
supplying through-holes of a partition insulating layer formed on an insulating substrate with a first solution which contains a first organic solvent and a film-forming material dissolved or dispersed therein, wherein the partition insulating layer is provided with the through-holes and recesses, and wherein the film-forming material is to be used as a material of a layer included in a display element;
selecting one out of the through-holes which is insufficient in supply of the first solution; and
supplying parts of the recesses surrounding the selected through-hole with a second solution which contains a second organic solvent and supplying the selected through-hole with a third solution which contains a third organic solvent and the film-forming material dissolved or dispersed therein.

20. The method according to claim 19, wherein the layer included in the display element is an organic layer included in an organic EL element, and wherein the film-forming material is an organic material.

21. The method according to claim 20, wherein the organic layer is an emission layer.

22. The method according to claim 20, wherein supplying the through-holes with the first solution, supplying the recesses surrounding the selected through-hole with the second solution, and supplying the selected through-hole with the third solution are carried out by ink-jet process.

23. The method according to claim 19, wherein supplying the through-holes with the first solution, supplying the recesses surrounding the selected through-hole with the second solution, and supplying the selected through-hole with the third solution are carried out by ink-jet process.

24. The method according to claim 19, wherein supplying the recesses surrounding the selected through-hole with the second solution is carried out before supplying the selected through-hole with the third solution.

25. The method according to claim 19, wherein the second solution consists of the second organic solvent and unavoidable impurities.

26. The method according to claim 19, wherein the second solution further contains the film-forming material.

27. The method according to claim 19, the first and third solutions are equal in composition to each other.
